(19) United States
(12) Patent Application Publication
(10) Pub. No.: US 2022/0316820 A1
(43) Pub. Date: Oct. 6, 2022

(54) WATER BLOCK REINFORCEMENT STRUCTURE

(71) Applicant: ASIA VITAL COMPONENTS CO., LTD., New Taipei City (TW)

(72) Inventors: Sung-Wei Lee, New Taipei City (TW); Kuan-Lin Huang, New Taipei City (TW); Ming-Tsung Yang, New Taipei City (TW)

(21) Appl. No.: 17/216,714

(22) Filed: Mar. 30, 2021

(51) Int. Cl. F28F 9/00; F28F 3/02; F28F 3/12

(52) U.S. Cl. CPC F28F 9/001; F28F 3/027; F28F 3/12

(57) ABSTRACT

A water block reinforcement structure includes a substrate and a cover body mated with the substrate to define a heat exchange chamber therebetween. At least one radiating fin assembly and at least one reinforcement section are disposed in the heat exchange chamber. The reinforcement section has an upper end connected with the inner face of the cover body by a connection means.

### BACKGROUND OF THE INVENTION

### 1. Field of the Invention

The present invention relates generally to the field of liquid heat dissipation structure, and more particularly to a heat dissipation reinforcement structure of a liquid (water) block.

### 2. Description of the Related Art

Along with the great enhancement of the requirement for big data and cloud computing service, the requirement for heat dissipation of related electronic products has become higher and higher. Especially, with respect to the server of a large-scale operation center, the operation density is increased so that the waste heat generated in the space with the same size is greatly increased. In order to reduce the energy consumed in heat dissipation, recently, liquid-cooling structure is employed to carry away the heat from the server and then dissipate the heat in other manner. This can solve the problem of high-density waste heat.

The water block is generally secured to a heat generation component (such as a chip) by means of a fixing unit. A working liquid with a certain water pressure passes through the water block to carry away the heat of the chip. Therefore, as shown in FIG. 6, the outer surface of the conventional water block 21 bears the compression pressure of the latch unit, while the interior 211 of the water block is subject to the action of the water pressure of the working liquid to produce expansion pressure. As a result, an upper cover 212 or a base seat of the water block 21 will swell or downward bend and deform to cause expansion and deformation. This will lead to malfunction of the water block.

It is therefore tried by the applicant to provide a water block reinforcement structure to solve the above problem and shortcoming existing in the conventional water block.

### SUMMARY OF THE INVENTION

It is therefore a primary object of the present invention to provide a water block reinforcement structure. By means of the reinforcement structure, the water block is able to bear the internal expansion pressure and the external compression pressure so as to reduce the expansion swelling deformation and compression concaving deformation.

To achieve the above and other objects, the water block reinforcement structure of the present invention includes a substrate having a heat exchange face and a heat contact face; and a cover body mated with the substrate to define a heat exchange chamber therebetween for a working liquid to flow through. At least one radiating fin assembly and at least one reinforcement section are distributed and arranged in the heat exchange chamber. The cover body has an inner face, an inlet and an outlet. The inner face faces the heat exchange face of the substrate. The inlet and the outlet are formed through the cover body in communication with the heat exchange chamber. The reinforcement section has an upper end connected with the inner face of the cover body by a connection means.

Still to achieve the above and other objects, the water block reinforcement structure of the present invention includes a substrate having a heat exchange face and a heat contact face; and a cover body mated with the substrate to define a heat exchange chamber therebetween for a working liquid to flow through. The cover body has an inner face, an inlet and an outlet. The inner face faces the heat exchange face of the substrate. The inlet and the outlet are formed through the cover body in communication with the heat exchange chamber. A radiating fin unit is disposed in the heat exchange chamber. The radiating fin unit has multiple radiating fin assemblies. A reinforcement section is disposed between each two adjacent radiating fin assemblies.

In the above water block reinforcement structure, the reinforcement section has a lower end integrally formed with the heat exchange face of the substrate.

In the above water block reinforcement structure, the reinforcement section has a lower end connected with the heat exchange face of the substrate by the connection means.

In the above water block reinforcement structure, the connection means includes welding.

In the above water block reinforcement structure, there are two reinforcement sections and three radiating fin assemblies in the heat exchange chamber. Each reinforcement section is disposed between each two adjacent radiating fin assemblies.

In the above water block reinforcement structure, the radiating fin assembly includes multiple radiating fins and the reinforcement section has a thickness thicker than the thickness of one single radiating fin.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1A is a perspective exploded view of the present invention;

FIG. 1B is a perspective assembled view of another embodiment of the present invention;

FIG. 2 is a perspective assembled view of the present invention;

FIG. 3 is a top view of another embodiment of the present invention, showing the substrate thereof;

FIGS. 4A and 4B are sectional assembled views of various embodiments of the present invention;

FIGS. 5A and 5B are load-displacement curve diagrams of the present invention; and

FIG. 5C is a measurement value table of pressure and deformation; and

FIG. 6 is a sectional view of a conventional water block, showing the expansion and deformation thereof.

### DETAILED DESCRIPTION OF THE PREFERRED EMBODIMENTS

The water block of the present invention is a part of a liquid-cooling loop. The water block mainly serves to contact a heat generation component to help in dissipating the heat of the heat generation component. The water block is in communication with an external heat dissipation unit (heat exchange fins or radiator) and/or pump via a water incoming tube and a water outgoing tube.

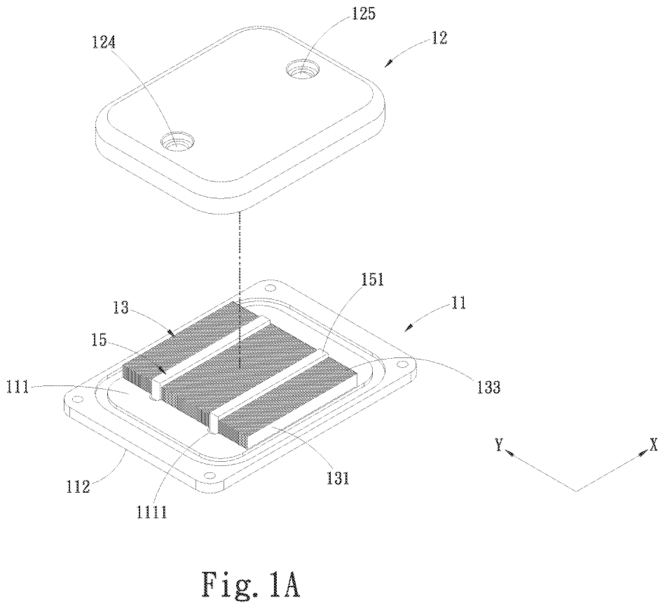

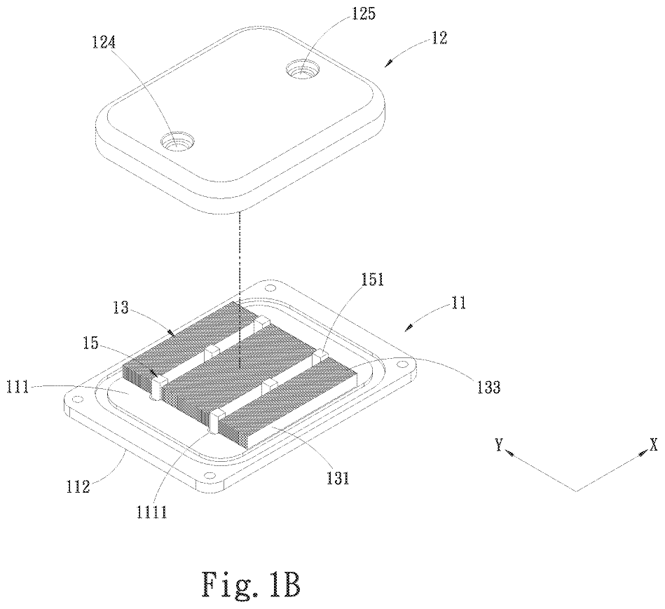

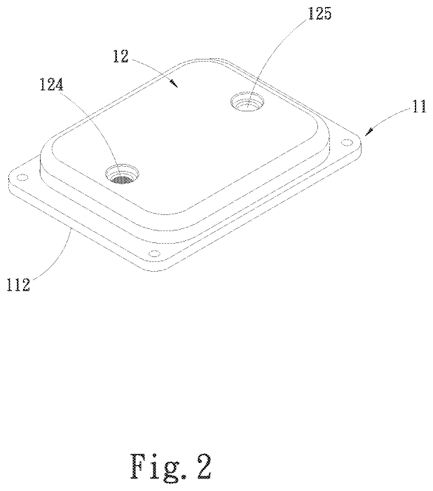

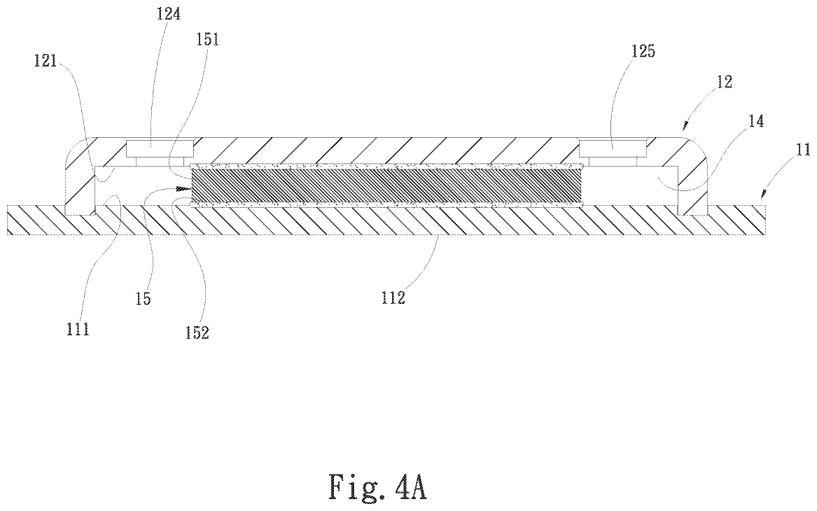

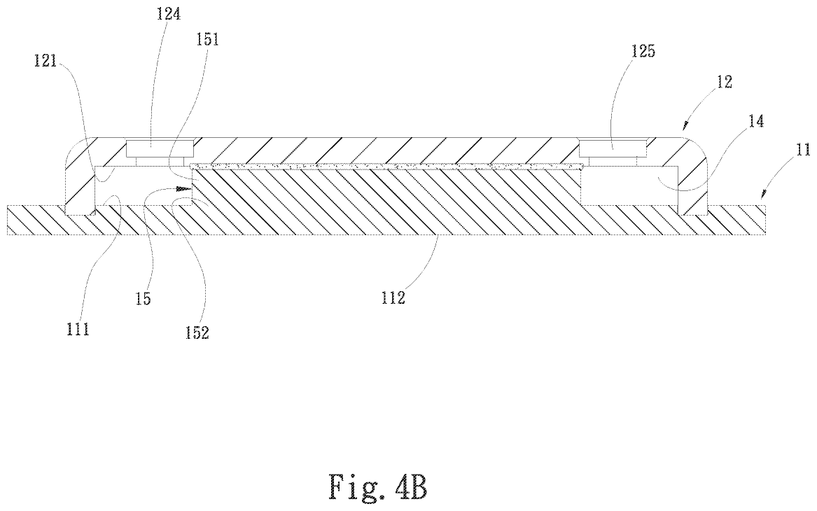

Please refer to FIGS. 1A, 1B and 2. FIG. 1A is a perspective exploded view of the present invention. FIG. 1B is a perspective assembled view of another embodiment of the present invention. FIG. 2 is a perspective assembled view of the present invention. The water block reinforcement structure of the present invention includes a substrate 11 and a cover body 12 mated with the substrate 11. A heat exchange chamber 14 (as shown in FIGS. 4A and 4B) is defined between the substrate 11 and the cover body 12 for a working liquid to flow through. At least one radiating fin assembly 13 and at least one reinforcement section 15 are arranged in the heat exchange chamber 14. In a preferred embodiment, the radiating fin assembly 13 is disposed corresponding to a heat source. The reinforcement section 15 is such disposed as to avoid the heat source. The substrate 11 has a heat exchange face 111 and a heat contact face 112. The cover body 12 has an inner face 121 (as shown in FIGS. 4A and 4B). The inner face 121 faces the heat exchange face 111 of the substrate 11. An inlet 124 and an outlet 125 are formed through the cover body 12 in communication with the heat exchange chamber 14. The inlet 124 and the outlet 125 are respectively connected with a liquid input tube and a liquid output tube for guiding the working liquid to flow into and out of the heat exchange chamber 14.

The radiating fin assembly 13 and the reinforcement section 15 are disposed on the heat exchange face 111 of the substrate 11. The radiating fin assembly 13 includes multiple radiating fins 131 arranged at intervals. A flow way is defined between each two adjacent radiating fins 131. In addition, the radiating fin assembly 13 defines two flowing sides 134, 135. In this embodiment, there are, but not limited to, three radiating fin assemblies 13 integrally formed on the heat exchange face 111 of the substrate 11. A top face 133 of the radiating fin assembly 13 faces the inner face 121 of the cover body 12. The top face 133 is not connected with the inner face 121 of the cover body 12.

The reinforcement section 15 is such as a rib (as shown in FIG. 1A) or a column (as shown in FIG. 1B) or a geometrical body in adjacency to the radiating fin assembly 13. The reinforcement section 15 has an upper end 151 and a lower end 152. In this embodiment, there are two reinforcement sections 15 in cooperation with the three radiating fin assemblies 13. In another embodiment, there is one reinforcement section 15 in cooperation with one or two radiating fin assemblies 13. In still another embodiment, there are multiple reinforcement sections 15 in cooperation with one radiating fin assembly 13.

In a preferred embodiment, there is one reinforcement section 15 positioned between each two adjacent radiating fin assemblies 13. Each reinforcement section 15 has a thickness thicker than the thickness of one single radiating fin 131. The reinforcement section 15 has a height slightly higher than the height of one single radiating fin 131.

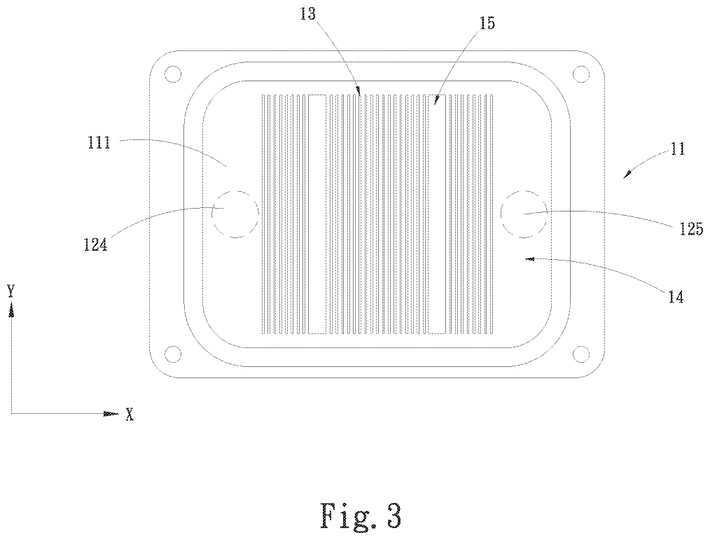

Moreover, in this embodiment, the radiating fin assemblies 13 and the reinforcement sections 15 are arranged in a direction X in parallel to the substrate 11 as shown in FIG. 1. The two flowing sides 134, 135 of the radiating fin assembly 13 are directed in the same direction (X) as the inlet 124 and the outlet 125. However, in a modified embodiment, as shown in FIG. 3, the radiating fin assemblies 13 and the reinforcement sections 15 are arranged in a direction Y in parallel to the substrate 11 as shown in FIG. 3. The inlet 124 and the outlet 125 and the two flowing sides 134, 135 are directed in different directions. That is, the inlet 124 and the outlet 125 are directed in the direction X, while the two flowing sides 134, 135 are directed in the direction Y.

Please further refer to FIGS. 4A and 4B, which are sectional assembled views of various embodiments of the present invention. Also referring to FIG. 1, the radiating fin assemblies 13 and/or the reinforcement sections 15 are integrally formed on the heat exchange face 111 of the substrate 11. Alternatively, the radiating fin assemblies 13 and/or the reinforcement sections 15 are separate components and connected on the heat exchange face 111 of the substrate 11 by a connection means (such as welding including brazing, soldering and ultrasonic welding (fusion)).

In a modified embodiment, as shown in FIG. 4A, in the case that the reinforcement sections 15 and the substrate 11 are separate components, the heat exchange face 111 of the substrate 11 can be previously formed with one or more locating channel 1111 to help in locating the lower end 152 of each reinforcement section 15. Then the lower end 152 of the reinforcement section 15 is welded with the heat exchange face 111 and the upper end 151 of the reinforcement section 15 is welded with the inner face 121 of the cover body 12. The locating channel is omissible. Instead, each reinforcement section 15 can be temporarily located on the heat exchange face 111 of the substrate 11 by means of solder and then the lower end 152 is welded with the heat exchange face 111. In still another modified embodiment, as shown in FIG. 4B, the reinforcement sections 15 are integrally formed on the heat exchange face 111 of the substrate 11. The lower ends 152 of the reinforcement sections 15 are integrally formed on the heat exchange face 111 of the substrate 11. The upper ends 151 are welded with the inner face 121 of the cover body 12.

The radiating fin assemblies 13 and the reinforcement sections 15 and the substrate 11 can be made of the same metal or different metals. The metals are such as, but not limited to, gold, silver, copper, aluminum, steel, titanium, or alloys thereof or combinations of these metals.

Furthermore, as shown in FIGS. 4A and 4B, after the cover body 12 is mated with the substrate 11, the inlet 124 and the outlet 125 are respectively positioned at two opposite ends of the radiating fin assembly 13, whereby the working fluid entering the heat exchange chamber 14 can flow from one end of the radiating fin assembly 13 to the other end thereof. In this case, the working fluid can fully heat-exchange with the radiating fin assembly 13.

After the reinforcement sections 15 are welded with the cover body 12 or welded with the substrate 11 and the cover body 12, the entire structural stiffness and anti-expansion pressure of the present invention are enhanced as shown in the following test data comparison diagrams and table:

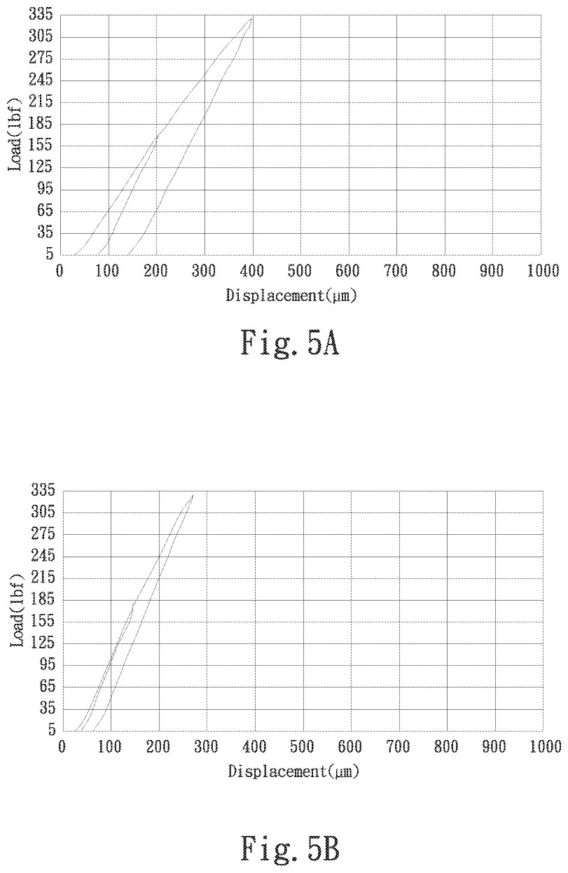

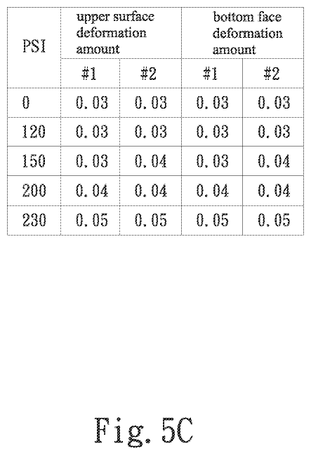

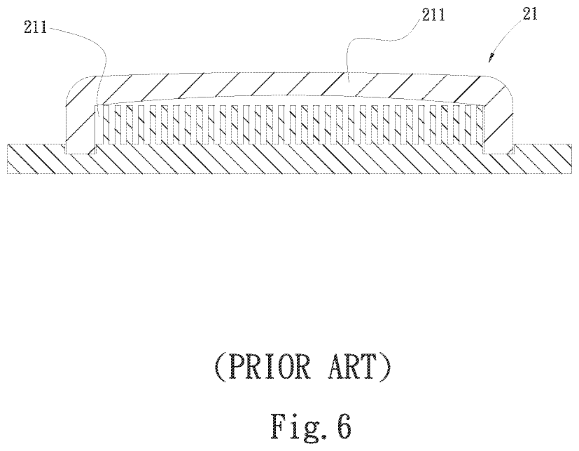

Please further refer to FIGS. 5A and 5B, which are load-displacement curve diagrams of stiffness tester with reinforcement sections and without reinforcement sections. In the diagrams, the transverse axis represents displacement, while the longitudinal axis represents load. FIG. 5A has no reinforcement sections 15, while FIG. 5B has reinforcement sections 15. The test load is increased from 170 lbf to 330 lbf. The linearity of the load-displacement curve with reinforcement sections 15 is steeper than the linearity of the load-displacement curve without reinforcement sections. In addition, the output stiffness test value of FIG. 5A is lower than 1000 lbf/mm and about 847 lbf/mm, while the output stiffness test value of FIG. 5B is higher than 1000 lbf/mm and about 1266 lbf/mm. The performance of FIG. 5B is obviously better than that of FIG. 5B.

Also, FIG. 5C is a measurement value table of the deformation of the upper surface, (that is, the outer surface of the cover body 12) and the bottom face, (that is, the heat contact face 112 of the substrate 11) of the liquid-cooling heat dissipation structure with the reinforcement sections 15. Please also refer to FIG. 1. In order to more objectively achieve the measurement values, two liquid-cooling heat dissipation structures with identical structures are tested. In the table, #1 and #2 represent the first and second liquid-cooling heat dissipation structures. As shown in FIG. 5C, when the pressure values are 0, 120 psi, 150 psi, 200 psi and 230 psi, the expansion deformation amounts of the upper surfaces and the bottom faces of the two liquid-cooling heat dissipation structures are respectively measured. It is shown in the drawing that when the pressure value rises from 0 to 150 psi, the deformation amounts of the upper surfaces and the bottom faces keep 0.03 mm. When the pressure value further rises to 200 psi and 230 psi, the deformation amounts of the upper surfaces and the bottom faces are 0.04 mm and 0.05 mm. This means that in the case that the upper ends 151 of the reinforcement sections 15 are welded with the inner face 121 of the cover body 12 (as shown in FIG. 4B) or the upper and lower ends 151, 152 of the reinforcement sections 15 are respectively welded with the inner face 121 of the cover body 12 and the heat exchange face 111 of the substrate 11 (as shown in FIG. 4A), the anti-expansion pressure can be enhanced to reduce the expansion deformation amounts of the substrate 11 and the cover body 12.

Accordingly, in the case that the reinforcement sections 15 are connected with the substrate 11 and/or the cover body 12 by a connection means (such as welding and ultrasonic welding), the water block is supported to bear the external compression pressure so as to reduce the compression and concaving deformation amount of the substrate 11 and the cover body 12. Also, the anti-internal expansion pressure is enhanced to reduce the expansion swelling deformation amounts of the substrate 11 and the cover body 12. In addition, the entire structural strength of the water block is enhanced.

The present invention has been described with the above embodiments thereof and it is understood that many changes and modifications in such as the form or layout pattern or practicing step of the above embodiments can be carried out without departing from the scope and the spirit of the invention that is intended to be limited only by the appended claims.

What is claimed is:

1. A water block reinforcement structure comprising:
a substrate having a heat exchange face and a heat contact face; and
a cover body mated with the substrate to define a heat exchange chamber therebetween for a working liquid to flow through, at least one radiating fin assembly and at least one reinforcement section being distributed and arranged in the heat exchange chamber, the cover body having an inner face, an inlet and an outlet, the inner face facing the heat exchange face of the substrate, the inlet and the outlet being formed through the cover body in communication with the heat exchange chamber, the reinforcement section having an upper end connected with the inner face of the cover body by a connection means.

2. The water block reinforcement structure as claimed in claim 1, wherein the reinforcement section has a lower end integrally formed with the heat exchange face of the substrate.

3. The water block reinforcement structure as claimed in claim 1, wherein the reinforcement section has a lower end connected with the heat exchange face of the substrate by the connection means.

4. The water block reinforcement structure as claimed in claim 1, wherein the connection means includes welding.

5. The water block reinforcement structure as claimed in claim 1, wherein the reinforcement section is a rib or a column or a geometrical body.
